(19) United States
(12) Patent Application Publication
(10) Pub. No.: US 2026/0012144 A1
(43) Pub. Date: Jan. 8, 2026

(54) RADIO FREQUENCY AMPLIFIER

(71) Applicant: Nuvoton Technology Corporation Japan, Kyoto (JP)

(72) Inventor: Hidefumi SUZAKI, Shiga (JP)

(21) Appl. No.: 19/328,335

(22) Filed: Sep. 15, 2025

Related U.S. Application Data
(63) Continuation of application No. PCT/JP2024/011317, filed on Mar. 22, 2024.
(60) Provisional application No. 63/492,956, filed on Mar. 29, 2023.
(60) Provisional application No. 63/493,214, filed on Mar. 30, 2023.

(51) Int. Cl. H03F 3/19; H03F 1/32

(52) U.S. Cl. CPC H03F 3/19; H03F 1/32; H03F 2200/246; H03F 2200/402; H03F 2200/451

(57) ABSTRACT

A radio frequency amplifier includes: a transistor; an input line; an output line; and a shunt circuit that is connected between ground and the input line or the output line, wherein the shunt circuit includes: a first series resonant circuit that includes an inductor and a capacitor that are connected in series and has first resonant frequency f1; a second series resonant circuit that includes an inductor and a capacitor that are connected in series and has second resonant frequency f2 that is different from the first resonant frequency; and a resistor that is connected between a first connection point and a second connection point, the first connection point being a connection location between the inductor and the capacitor in the first series resonant circuit, the second connection point being a connection location between the inductor and the capacitor in the second series resonant circuit.

### CROSS REFERENCE TO RELATED APPLICATIONS

This is a continuation application of PCT International Patent Application No. PCT/JP2024/011317 filed on Mar. 22, 2024, designating the United States of America, which is based on and claims priority of U.S. Provisional Patent Application No. 63/492,956 filed on Mar. 29, 2023 and U.S. Provisional Patent Application No. 63/493,214 filed on Mar. 30, 2023. The entire disclosures of the above-identified applications, including the specifications, drawings and claims are incorporated herein by reference in their entirety.

### FIELD

The present disclosure relates to a radio frequency amplifier, and particularly relates to a radio frequency amplifier that is highly efficient and has superior linearity over a wide bandwidth.

### BACKGROUND

With the evolution of mobile communication systems, the amount of information transmission required for wireless communication systems is expanding. In order to transmit a large amount of information, multi-carrier communication methods such as orthogonal frequency-division multiplexing (OFDM), in which a plurality of items of information are carried on a plurality of carrier waves and the information is sent all at once, have become popular. In a multi-carrier communication system, a plurality of radio frequency signals having different frequencies exist simultaneously within a defined occupied band, whereby intermodulation distortion occurs due to interference between the signals within the occupied band. It is known that in general, when a plurality of radio frequency signals having frequencies that are different are inputted into a radio frequency amplifier, the second-order distortion components at the difference frequencies between the frequencies that are different worsen the intermodulation distortion. Since intermodulation distortion results in interference waves within another, adjacent occupied band, intermodulation distortion is required to be kept low. In order to reduce intermodulation distortion, it is known that reducing the impedance at the difference frequencies is effective with respect to the matching circuit connected to the transistor for radio frequency signal amplification. The maximum difference frequency value is the difference between the minimum frequency and the maximum frequency within the occupied bandwidth. As the amount of information transmitted expands and the occupied bandwidth becomes wider, the maximum difference frequency value also expands. Thus, in recent wireless communication systems, it is necessary to reduce the impedance at difference frequencies over a wider bandwidth. The term “impedance of the difference frequency” refers to the impedance with respect to a signal having the frequency of the difference frequency, and may also be referred to as the “difference frequency impedance” or the “impedance at the difference frequency”.

For example, Patent Literature (PTL) 1 discloses a method in which, in order to reduce the impedance, over a wide bandwidth, of a matching circuit connected to a transistor, a plurality of circuits that reduce difference frequency impedance and have different resonant frequencies are combined. In this method, transmission lines and capacitors are directly connected, a plurality of different series resonant circuits are formed using the inductance components in the transmission lines and the capacitors, and difference frequency impedance is reduced by connecting the plurality of series resonant circuits in shunt to transistors.

### CITATION LIST

### Patent Literature

PTL 1: WO 2020/202532
PTL 2: Japanese Patent No. 5571047

### SUMMARY

### Technical Problem

However, when, as disclosed in PTL 1, a plurality of circuits that reduce difference frequency impedance and have different resonant frequencies are present in an amplifier, antiresonance occurs at the frequencies between adjacent resonant frequencies, resulting in bands that have high impedance. When bands that have high difference frequency impedance are present, the intermodulation distortion worsens. In order to prevent this antiresonance, in PTL 2, a resistor is connected in series to a difference frequency impedance reduction circuit that is formed by connecting an inductor and a capacitor in series. This resistor converts an amplified radio frequency signal into heat, which causes a decrease in the efficiency of the radio frequency amplifier. Furthermore, when the bias voltage is shared through the inductor and the transmission line of the series resonant circuit, a drop in voltage occurs, and this becomes a cause for increased power consumption and the deterioration of radio frequency properties.

Accordingly, the present disclosure provides a radio frequency amplifier that solves the above-described problem, has low intermodulation distortion, and is capable of highly efficient operation by reducing the impedance at difference frequencies over a wide bandwidth, even when the occupied bandwidth increases and the difference frequencies increase.

### Solution to Problem

A radio frequency amplifier according to one aspect of the present disclosure includes: a transistor; an input line that transmits a radio frequency (RF) signal to be inputted into the transistor; an output line that transmits an RF signal that is outputted from the transistor; and a shunt circuit that is connected between ground and the input line or the output line, wherein the shunt circuit includes: a first series resonant circuit that is connected between a node and the ground, includes a first inductor element and a first capacitor element that are connected in series, and has a first resonant frequency, the node being on the input line or the output line; a second series resonant circuit that is connected between the node and the ground, includes a second inductor element and a second capacitor element that are connected in series, and has a second resonant frequency that is different from the first resonant frequency; and a first impedance element that is connected between a first connection point and a second connection point and includes a resistance component, the first connection point being a connection location between the first inductor element and the first capacitor element, the second connection point being a connection location between the second inductor element and the second capacitor element.

### Advantageous Effects

The present disclosure makes it possible to provide a radio frequency amplifier that is highly efficient and, compared to the conventional amplifier, has linearity over a wide bandwidth.

### BRIEF DESCRIPTION OF DRAWINGS

These and other advantages and features will become apparent from the following description thereof taken in conjunction with the accompanying Drawings, by way of non-limiting examples of embodiments disclosed herein.

FIG. 1 is a circuit diagram illustrating a configuration example of a radio frequency amplifier according to Embodiment 1.

FIG. 2 is a circuit diagram illustrating a configuration example of a radio frequency amplifier according to Comparative Example 1.

FIG. 3 is a circuit diagram illustrating a configuration example of a radio frequency amplifier according to Comparative Example 2.

FIG. 4 is a diagram illustrating the results of a simulation of the impedance observed from the drain of the transistor for Embodiment 1, Comparative Example 1, and Comparative Example 2.

FIG. 5 is a diagram illustrating the results of a simulation of the insertion loss from the drain of the transistor to the output terminal for Embodiment 1, Comparative Example 1, and Comparative Example 2.

FIG. 6 is a diagram illustrating the resistance value when the two series resonant circuits of the radio frequency amplifier according to Embodiment 1 are connected, and the results of a simulation of the difference frequency impedance and the pass loss.

FIG. 7 is a circuit diagram illustrating a configuration example of a radio frequency amplifier according to Embodiment 2.

FIG. 8 is a diagram illustrating the results of a simulation of the impedance observed from the drain of the transistor for Embodiment 2 and Comparative Example 1.

FIG. 9 is a diagram illustrating the results of a simulation of the insertion loss from the drain of the transistor to the output terminal for Embodiment 2 and Comparative Example 1.

FIG. 10 is a circuit diagram illustrating a configuration example of a radio frequency amplifier according to a variation of Embodiment 2.

FIG. 11 is a circuit diagram illustrating a configuration example of a radio frequency amplifier according to Embodiment 3.

FIG. 12 is a circuit diagram illustrating a configuration example of a radio frequency amplifier according to Embodiment 4.

FIG. 13 is a circuit diagram illustrating a configuration example of a radio frequency amplifier according to a variation of Embodiment 4.

FIG. 14 is a circuit diagram illustrating a configuration example of a shunt circuit including a bridge circuit other than a resistor.

### DESCRIPTION OF EMBODIMENTS

The radio frequency amplifier of the present disclosure is described below with reference to the Drawings. However, detailed descriptions may be omitted. For example, detailed descriptions of matters that are already well known and duplicate descriptions for features that are substantially the same may be omitted. In addition, the Drawings are not necessarily strictly illustrated. These are intended to prevent unnecessary redundancy in the following descriptions and to facilitate the understanding of those skilled in the art.

It should be noted that each of the embodiments described below shows a specific example of the present disclosure. The numerical values, shapes, materials, constituent elements, the arrangement and connection of the constituent elements, steps, and the like indicated in the following embodiments are mere examples for those skilled in the art to sufficiently understand the present disclosure, and thus are not intended to limit the matters recited in the claims.

### Embodiment 1

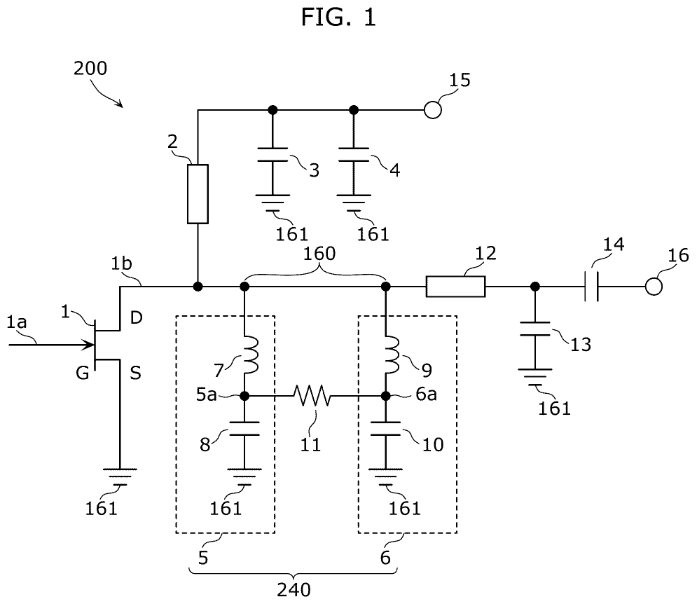

FIG. 1 is a circuit diagram illustrating radio frequency amplifier 200 according to Embodiment 1. Radio frequency amplifier 200 includes transistor 1 for amplifying radio frequency signals. Transistor 1 has: gate G that is connected to input line 1a that transmits a radio frequency (RF) signal to be inputted into transistor 1; drain D that is connected to output line 1b that transmits an RF signal that is outputted from transistor 1; and source S that is connected to ground 161.

One end of transmission line 2 is connected to drain D of transistor 1, and the other end of transmission line 2 is connected to bypass capacitors 3 and 4 and bypassed in a radio frequency band. At the connection point between transmission line 2 and bypass capacitors 3 and 4, power supply terminal 15 that supplies direct current voltage is provided. Transmission line 2 and bypass capacitors 3 and 4 constitute a drain bias circuit for supplying, to drain D, the drain bias voltage required to operate transistor 1.

While power supply terminal 15 is bypassed in the radio frequency band by bypass capacitors 3 and 4, openness with direct current is ensured. As the electrical length of transmission line 2, one end of which is bypassed in the radio frequency band, increases, the impedance observed when viewing transmission line 2 from drain D of transistor 1, which is the other end of transmission line 2, increases. This impedance is largest when the electrical length of transmission line 2 is an electrical length that is a quarter wavelength (λ/4) of the radio frequency signal to be amplified. If the impedance, in the direction of power supply terminal 15, from the connection point between drain D of transistor 1 and transmission line 2 is made a sufficiently large value, leakage of amplified radio frequency signals to power supply terminal 15 can be prevented.

Shunt circuit 240 that includes first series resonant circuit 5 and second series resonant circuit 6 is connected between ground 161 and output line 1b (here, node 160) that is connected to drain D of transistor 1. Shunt circuit 240 is a circuit that suppresses the signal component of a specific frequency (in other words, the difference frequency) by lowering the impedance of the specific frequency (in other words, the difference frequency).

First series resonant circuit 5 is formed by inductor 7 that is an example of the first inductor element and capacitor 8 that is an example of the first capacitor element being connected in series at first connection point 5a. That is, one end of inductor 7 is connected to drain D (here, node 160 on output line 1b) of transistor 1, and one end of capacitor 8 is connected to ground 161. It should be noted that conversely, one end of capacitor 8 may be connected to drain D of transistor 1, and one end of inductor 7 may be connected to ground 161.

Second series resonant circuit 6 is formed by inductor 9 that is an example of the second inductor element and capacitor 10 that is an example of the second capacitor element being connected in series at second connection point 6a. That is, one end of inductor 9 is connected to drain D (here, node 160 on output line 1b) of transistor 1, and one end of capacitor 10 is connected to ground 161. It should be noted that conversely, one end of capacitor 10 may be connected to drain D of transistor 1, and one end of inductor 9 may be connected to ground 161. Furthermore, node 160 to which first series resonant circuit 5 is connected and node 160 to which second series resonant circuit 6 is connected are different locations on output line 1b in FIG. 1, but these may be the same location on output line 1b.

Resonant frequency (also referred to as first resonant frequency) f1 of first series resonant circuit 5 and resonant frequency (also referred to as second resonant frequency) f2 of second series resonant circuit 6 can be expressed as shown below, by using inductance value L1 of inductor 7 and capacitance value C1 of capacitor 8, and inductance value L2 of inductor 9 and capacitance value C2 of capacitor 10, respectively.

$$\begin{matrix}f 1 = 1 / 2 π \sqrt{L 1 \times C 1} \\ f 2 = 1 / 2 π \sqrt{L 2 \times C 2}\end{matrix} \qquad [ Math . 1 ]$$

Resonant frequencies f1 and f2 are selected as the frequency bands (i.e., difference frequencies) for which impedance reduction is desired, as viewed from drain D of transistor 1 (that is, between drain D and ground 161). For example, when the occupied bandwidth of the radio frequency signal to be amplified by radio frequency amplifier 200 is assumed to be up to about 1,000 MHZ, L1 and C1, and L2 and C2 are selected such that f1=650 MHz and f2=900 MHZ, respectively. The high/low relationship between resonant frequencies f1 and f2 may be switched.

First connection point 5a, which is the connection point between inductor 7 and capacitor 8 of first series resonant circuit 5, and second connection point 6a, which is the connection point between inductor 9 and capacitor 10 of second series resonant circuit 6, are connected by resistor 11, which is an example of the first impedance element that includes a resistance component. In other words, in the present embodiment, shunt circuit 240 includes first series resonant circuit 5, second series resonant circuit 6, and resistor 11 that bridges these two series resonant circuits.

Resistor 11 is sufficient as long as it is an impedance element that includes a resistance component. The connection order of inductor 7 and capacitor 8 and the connection order of inductor 9 and capacitor 10 may be switched, but due to connecting resistor 11, new paths from first series resonant circuit 5 to drain D of transistor 1 are added, via resistor 11 and second series resonant circuit 6. There are four combinations of these paths (paths 1 to 4) as shown below, and the path details and impedance Z for each path are expressed as follows. R denotes the resistance value of resistor 11.

$$\begin{matrix}Path 1 : inductor 7 \to resistor 11 \to inductor 9 Z = j ω L 1 + R + j ω L 2 \\ Path 2 : inductor 7 \to resistor 11 \to capacitor 10 Z = j ω L 1 + R + \frac{1}{j ω L 2} \\ Path 3 : capacitor 8 \to resistor 11 \to inductor 9 Z = \frac{1}{j ω L 1} + R + j ω L 2 \\ Path 4 : capacitor 8 \to resistor 11 \to capacitor 10 Z = \frac{1}{j ω C 1} + R + \frac{1}{j ω L 2}\end{matrix} \qquad [ Math . 2 ]$$

In paths 1 to 4, the frequency at which the signal passes is higher than the resonant frequency of each of first series resonant circuit 5 and second series resonant circuit 6. The combination with the highest impedance at the frequency at which the signal passes is path 1, which allows for inhibiting, to the lowest level, the signal attenuation due to resistor 11.

Transmission line 12 is connected to drain D of transistor 1. On the other side of transmission line 12, capacitor 13 is connected to a shunt, and further, capacitor 14 is connected in series. On the other side of capacitor 14, output terminal 16 is provided. Transmission line 12, capacitor 13, and capacitor 14 serve as a matching circuit for converting the impedance from drain D of transistor 1 to output terminal 16. The inductor and the capacitor of each of first series resonant circuit 5 and second series resonant circuit 6 are selected to the extent that they do not interfere with the role of this matching circuit. Furthermore, the connection position of first series resonant circuit 5 and second series resonant circuit 6 may be connected at a position close to drain D of transistor 1.

If, between transistor 1, and first series resonant circuit 5 and second series resonant circuit 6, there is an impedance element that attenuates or blocks the signal, the impedance reduction effect due to the series resonance by first series resonant circuit 5 and second series resonant circuit 6 will not be sufficiently obtained. For example, if there is an impedance element of 20Ω between transistor 1, and first series resonant circuit 5 and second series resonant circuit 6, even if impedance close to 0Ω can be achieved by first series resonant circuit 5 and second series resonant circuit 6, the difference frequency impedance observed from transistor 1 cannot be reduced to less than 20Ω. Given that the impedance generated by the antiresonance is at most 20Ω, this impedance element may be less than 20Ω. This impedance element includes not only resistors but also individual parts such as transmission lines, inductors, and capacitors that include resistance components, as well as parasitic elements in these parts.

Next, radio frequency amplifier 200 according to Embodiment 1 will be described with a focus on the differences from radio frequency amplifiers according to comparative examples.

### Comparative Example 1

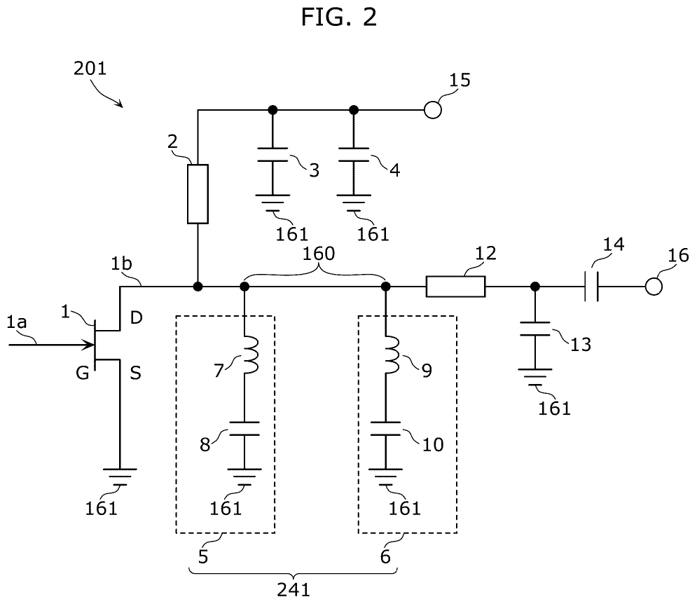

FIG. 2 is a circuit diagram illustrating a configuration example of radio frequency amplifier 201 according to Comparative Example 1. Instead of shunt circuit 240 in Embodiment 1 illustrated in FIG. 1, radio frequency amplifier 201 includes shunt circuit 241 that has a different form. Hereinafter, the same symbols are appended to constituent elements that are the same as those in Embodiment 1, and description will focus on the points of difference from Embodiment 1.

Similarly to Embodiment 1, shunt circuit 241 according to the present comparative example includes first series resonant circuit 5 and second series resonant circuit 6, but differing from Embodiment 1, the present comparative example does not include resistor 11 that bridges first series resonant circuit 5 and second series resonant circuit 6. It should be noted that resonant frequency f1 of first series resonant circuit 5 and resonant frequency f2 of second series resonant circuit 6 are the same as in Embodiment 1, and are set to resonant frequency f1=650 MHz and resonant frequency f2=900 MHz as an example.

### Comparative Example 2

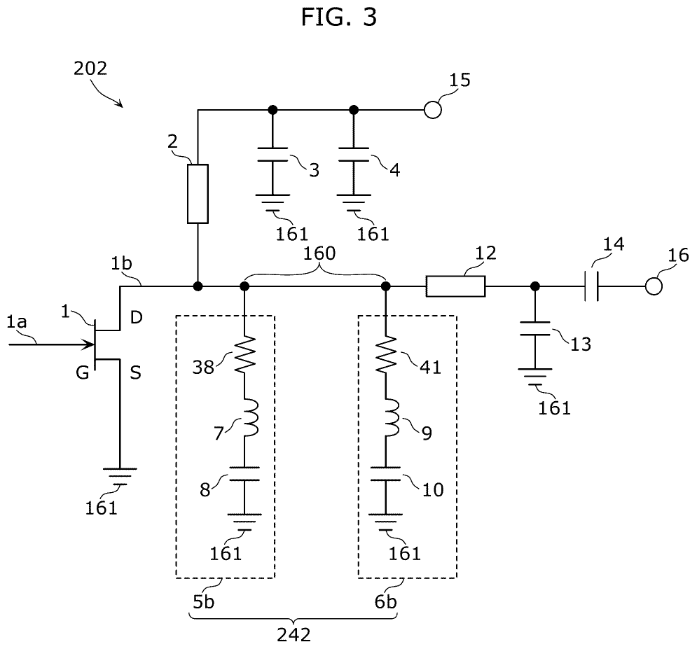

FIG. 3 is a circuit diagram illustrating a configuration example of radio frequency amplifier 202 according to Comparative Example 2. Instead of shunt circuit 240 in Embodiment 1 illustrated in FIG. 1, radio frequency amplifier 202 includes shunt circuit 242 that has a different form. Hereinafter, the same symbols are appended to constituent elements that are the same as those in Embodiment 1, and description will focus on the points of difference from Embodiment 1.

Shunt circuit 242 that includes first series resonant circuit 5b and second series resonant circuit 6b is connected between ground 161 and output line 1b (here, node 160) that is connected to drain D of transistor 1. First series resonant circuit 5b is formed by, in addition to inductor 7 and capacitor 8 that are connected in series as in Embodiment 1, resistor 38 being connected in series. Second series resonant circuit 6b is formed by, in addition to inductor 9 and capacitor 10 being connected in series as in Embodiment 1, resistor 41 being connected in series. It should be noted that resonant frequency f1 of first series resonant circuit 5b and resonant frequency f2 of second series resonant circuit 6b are the same as in Embodiment 1, and are set to resonant frequency f1=650 MHz and resonant frequency f2=900 MHz as an example.

It should be noted that as in Comparative Example 1, shunt circuit 242 according to the present comparative example does not include resistor 11 that bridges first series resonant circuit 5b and second series resonant circuit 6b.

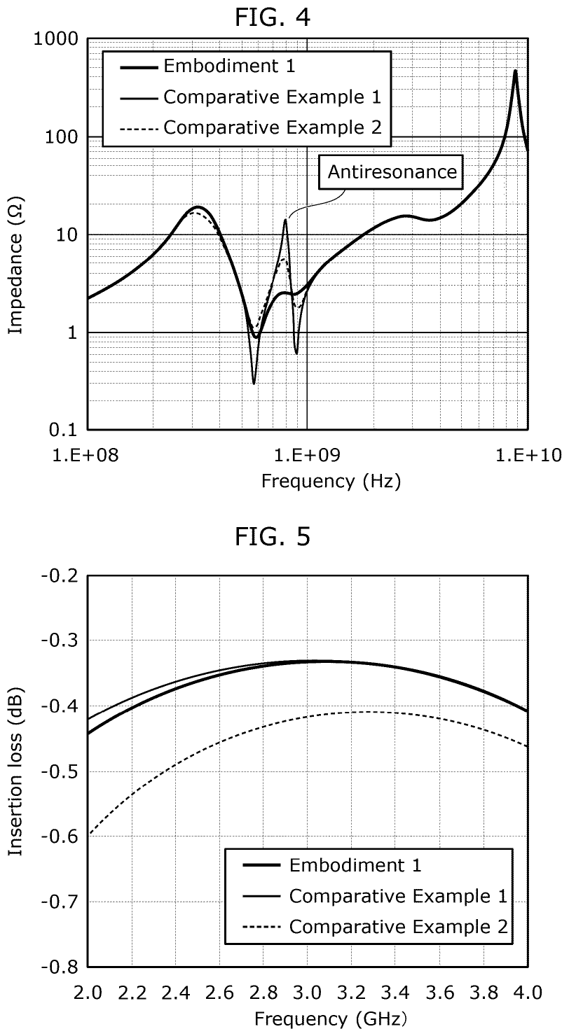

FIG. 4 is a diagram illustrating the results of a simulation of the impedance (vertical axis) observed from drain D of transistor 1 for the radio frequency amplifiers according to Embodiment 1, Comparative Example 1, and Comparative Example 2. The horizontal axis represents frequency. FIG. 4 can be considered to be a diagram that illustrates the impedance at difference frequencies.

Embodiment 1, Comparative Example 1, and Comparative Example 2 correspond to trajectories shown by a thick solid line, a thin solid line, and a dashed line, respectively. From the trajectories of Comparative Example 1 and Comparative Example 2, the resonant frequencies of first series resonant circuits 5 and 5b and second series resonant circuits 6 and 6b can be confirmed near 650 MHz and 900 MHZ, respectively, while the maximum value of impedance due to antiresonance is observed near 800 MHZ, the frequency in between. Compared to Comparative Example 1, in the antiresonance in Comparative Example 2, it can be confirmed that the impedance value is inhibited by resistors 38 and 41 connected in series in first series resonant circuit 5b and second series resonant circuit 6b, respectively. In the trajectory of Embodiment 1, it can be confirmed that the antiresonance observed in Comparative Example 1 and Comparative Example 2 is sufficiently inhibited, and the impedance at difference frequencies is reduced over a wide bandwidth of 650 MHz to 900 MHZ.

FIG. 5 is a diagram illustrating the results of a simulation of the insertion loss (vertical axis) from drain D of transistor 1 to output terminal 16, for the radio frequency amplifiers according to Embodiment 1, Comparative Example 1, and Comparative Example 2. In order to compare the loss inside the radio frequency amplifiers, the calculated results exclude loss due to reflection. In all circuits, circuit constants have been selected such that the insertion loss is lowest around 3 GHZ. The results indicate that the insertion loss is lowest (the upper position on the vertical axis in FIG. 5) for Comparative Example 1, which has no resistance components in the first series resonant circuit or the second series resonant circuit, and the insertion loss in Embodiment 1 is about equal to that in Comparative Example 1. For Comparative Example 2, in which resistors 38 and 41 are disposed in series in the first series resonant circuit and the second series resonant circuit, respectively, it can be confirmed that the insertion loss increases (the lower position on the vertical axis in FIG. 5).

From the results of FIG. 4 and FIG. 5, it can be confirmed that radio frequency amplifier 200 according to Embodiment 1 can stably reduce the difference frequency impedance over a wider bandwidth by inhibiting the generation of antiresonance (refer to FIG. 4), with almost no increase in the insertion loss of the circuit (refer to FIG. 5).

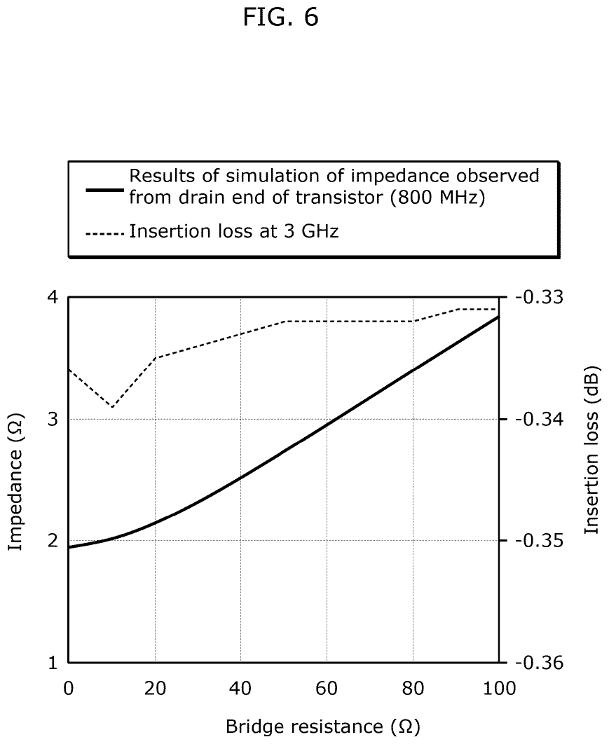

FIG. 6 is a diagram illustrating the resistance value (“Bridge resistance” on the horizontal axis) of resistor 11 connected between first series resonant circuit 5 and second series resonant circuit 6 in radio frequency amplifier 200 of Embodiment 1, and the results of a simulation of the impedance at the difference frequency (the left vertical axis; the trajectory of the solid line) near 800 MHZ and the insertion loss (the right vertical axis; the trajectory of the dashed line) near 3 GHZ. As the resistance (“Bridge resistance” on the horizontal axis) decreases, the impedance at the difference frequency becomes lower, as illustrated by the solid line; however, the insertion loss of the circuit becomes higher (in other words, becomes lower on the right vertical axis), as illustrated by the dashed line. Furthermore, it can be observed that: as illustrated by the solid line, in order to reduce the impedance at the difference frequency to 3Ω or less, the resistance value of resistor 11 (“Bridge resistance” on the horizontal axis) may be a resistance value of approximately 60Ω or less; and moreover, as illustrated by the dashed line, in order to prevent the worsening of insertion loss, the resistance value of resistor 11 (“Bridge resistance” on the horizontal axis) may be selected to be approximately 30Ω or greater.

As described above, radio frequency amplifier 200 according to Embodiment 1 includes: transistor 1; input line 1a that transmits a radio frequency (RF) signal to be inputted into transistor 1; output line 1b that transmits an RF signal that is outputted from transistor 1; and shunt circuit 240 that is connected between output line 1b and ground 161, wherein shunt circuit 240 includes: first series resonant circuit 5 that is connected between node 160 and ground 161, includes inductor 7 and capacitor 8 that are connected in series, and has first resonant frequency f1, node 160 being on output line 1b; second series resonant circuit 6 that is connected between node 160 and ground 161, includes inductor 9 and capacitor 10 that are connected in series, and has second resonant frequency f2 that is different from first resonant frequency f1; and a first impedance element that is connected between first connection point 5a and second connection point 6a and includes a resistance component, first connection point 5a being a connection location between inductor 7 and capacitor 8, second connection point 6a being a connection location between inductor 9 and capacitor 10.

Thus, the first impedance element that includes the resistance component and that bridges first series resonant circuit 5 and second series resonant circuit 6 is provided between first series resonant circuit 5 and second series resonant circuit 6. Thus, even if the occupied bandwidth increases and the difference frequencies increase, the impedance at difference frequencies is reduced over a wide bandwidth, resulting in the realization of a radio frequency amplifier that has low intermodulation distortion and is capable of highly efficient operation.

Here, the first impedance element that includes the resistance component is a resistor element (resistor 11). This makes it simple to realize the first impedance element that includes the resistance component.

At this time, the resistance component of the resistor element (resistor 11) may be 60Ω or less. This makes it possible to reduce the impedance at the difference frequency to 3Ω or less.

Furthermore, the resistance component of the resistor element (resistor 11) may be 30Ω or greater. This inhibits the worsening of the insertion loss.

It should be noted that in first series resonant circuit 5 and second series resonant circuit 6, the inductor is connected closer to node 160 than the capacitor is, but this order is not limiting, and conversely, the capacitor may be connected closer to node 160 than the inductor is.

Furthermore, an impedance element that blocks signals of first resonant frequency f1 and second resonant frequency f2 is absent between gate G or drain D of transistor 1 (in the present embodiment, drain D) and shunt circuit 240. More specifically, the impedance of the impedance element is 20Ω or greater. In other words, the impedance between drain D of transistor 1 and shunt circuit 240 may be less than 20Ω. Accordingly, the impedance reduction effect due to the series resonance of the series resonant circuits that form shunt circuit 240 can be sufficiently obtained.

### Embodiment 2

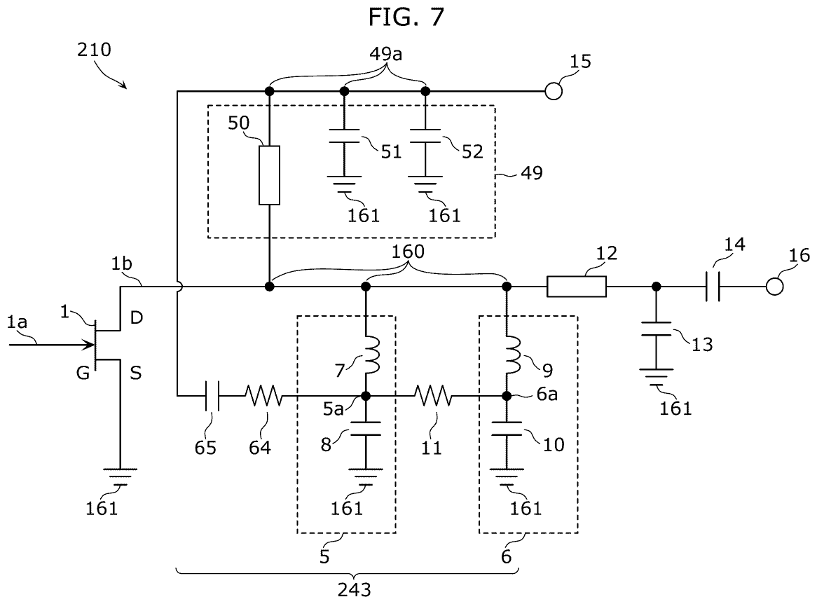

FIG. 7 is a circuit diagram illustrating radio frequency amplifier 210 according to Embodiment 2. Radio frequency amplifier 210 has basically the same configuration as Embodiment 1, but is different from Embodiment 1 in that radio frequency amplifier 210 includes, as shunt circuit 243, third series resonant circuit 49 in addition to first series resonant circuit 5 and second series resonant circuit 6, and further includes resistor 64 and capacitor 65 that are connected in series and bridge third series resonant circuit 49 and first series resonant circuit 5. Hereinafter, the same symbols are appended to constituent elements that are the same as those in Embodiment 1, and description will focus on the points of difference from Embodiment 1.

One end of transmission line 50, which is an example of a third inductor element, is connected to drain D of transistor 1, and the other end of transmission line 50 is connected to bypass capacitors 51 and 52, which are examples of third capacitor elements, and bypassed in a radio frequency band. Power supply terminal 15 is provided to third connection point 49a, which is the connection point between transmission line 50 and bypass capacitors 51 and 52. Transmission line 50 and bypass capacitors 51 and 52 constitute a drain bias circuit for supplying, to drain D, the drain bias voltage required to operate transistor 1. In the present embodiment, transmission line 50 and bypass capacitors 51 and 52 are connected between node 160 and ground 161, and the third inductor element (that is, transmission line 50) and the third capacitor elements (that is, bypass capacitors 51 and 52), which are connected in series, are included and can be said to constitute third series resonant circuit 49 that has third resonant frequency f3 that is different from first resonant frequency f1 and second resonant frequency f2.

While power supply terminal 15 is bypassed in the radio frequency band by bypass capacitors 51 and 52, openness with direct current is ensured. As the electrical length of transmission line 50, one end of which is bypassed in the radio frequency band, increases, the impedance observed when viewing transmission line 50 from drain D of transistor 1, which is the other end, increases. This impedance is largest when the electrical length of transmission line 50 is an electrical length that is a quarter wavelength (λ/4) of the radio frequency signal to be amplified. If the impedance, in the direction of power supply terminal 15, from the connection point between drain D of transistor 1 and transmission line 50 is made a sufficiently large value, leakage of amplified radio frequency signals to power supply terminal 15 can be prevented.

As in Embodiment 1, first series resonant circuit 5 and second series resonant circuit 6 are connected to transistor 1. In the present embodiment, first series resonant circuit 5, second series resonant circuit 6, and third series resonant circuit 49 together constitute shunt circuit 243 that is connected between output line 1b and ground 161. When L3 denotes the inductance component included in transmission line 50 and C3 denotes the sum of the capacitance values of bypass capacitors 51 and 52, resonant frequency f3 of third series resonant circuit 49 (also referred to as “third resonant frequency f3”) can be expressed as shown below.

$$f 3 = 1 / 2 π \sqrt{L 3 \times C 3} \qquad [ Math . 3 ]$$

For the value of C3, a sufficiently large value is selected to inhibit leakage of radio frequency components to power supply terminal 15.

The three resonant frequencies f1, f2, and f3 are selected to be frequency bands for which impedance reduction is desired, as viewed from drain D of transistor 1. For example, assuming that the occupied bandwidth of the radio frequency signal is up to about 600 MHz, L1 and C1, L2 and C2, and L3 and C3 are selected such that f1=90 MHz, f2=450 MHZ, and f3=10 MHZ, respectively. In this example, it can be stated that first resonant frequency f1, second resonant frequency f2, and third resonant frequency f3 are arranged at equal intervals on a logarithmic scale. It should be noted that the high/low relationships between resonant frequencies f1, f2, and f3 may be switched.

Furthermore, in shunt circuit 243, third connection point 49a, which is the connection point between transmission line 50 and bypass capacitors 51 and 52, and first connection point 5a, which is the connection point between inductor 7 and capacitor 8 of first series resonant circuit 5, are connected using resistor 64 and capacitor 65 that are connected in series. In other words, shunt circuit 243 has resistor 64 and capacitor 65 that are connected in series. Resistor 64 is a resistor that bridges first series resonant circuit 5 and third series resonant circuit 49, and capacitor 65 prevents the direct current voltage applied from power supply terminal 15 from being applied to drain D of transistor 1 via resistor 64 and inductor 7. It should be noted that using a resistor and a capacitor, third connection point 49a, which is the connection point between transmission line 50 and bypass capacitors 51 and 52 of third series resonant circuit 49, may be connected to second connection point 6a, which is the connection point between inductor 9 and capacitor 10 of second series resonant circuit 6.

Furthermore, the connection position of third series resonant circuit 49 may be connected at a position close to drain D of transistor 1. If, between transistor 1 and third series resonant circuit 49, there is an impedance element that attenuates or blocks the signal, the impedance reduction effect due to the series resonance will not be sufficiently obtained. For example, if there is an impedance element of 20Ω between transistor 1 and third series resonant circuit 49, even if impedance close to a short circuit can be achieved by third series resonant circuit 49, the difference frequency impedance observed from transistor 1 cannot be reduced to less than 20Ω. Given that the impedance generated by the antiresonance is at most 20Ω, this impedance element may be less than 20Ω. This impedance element includes not only resistors but also individual parts such as transmission lines, inductors, and capacitors that include resistance components, as well as parasitic elements in these parts.

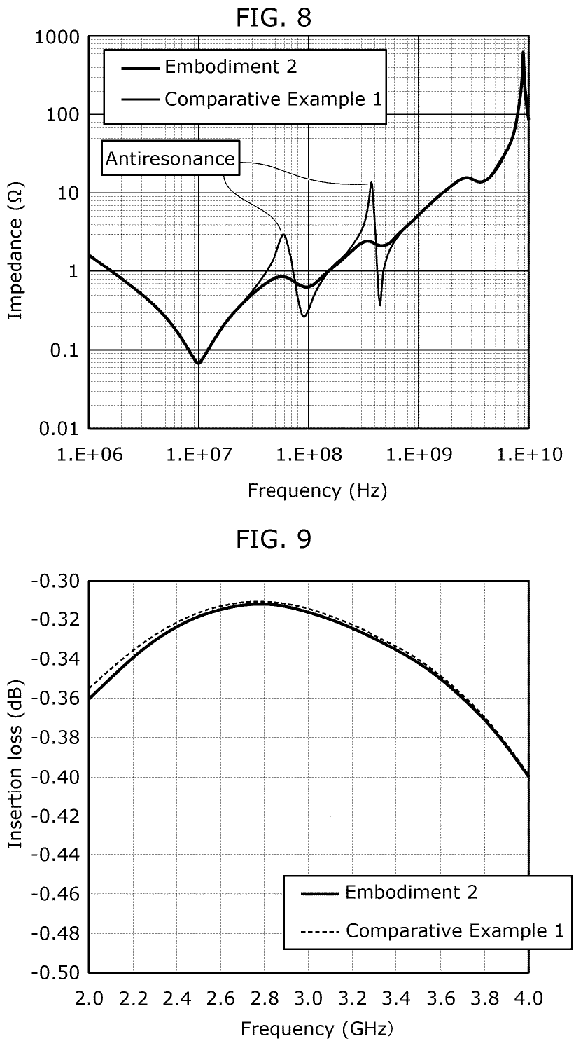

FIG. 8 is a diagram illustrating the results of a simulation of the impedance (vertical axis) observed from drain D of transistor 1 for the radio frequency amplifiers according to Embodiment 2 and Comparative Example 1. The horizontal axis represents frequency. FIG. 8 can be considered to be a diagram that illustrates the impedance at difference frequencies. Embodiment 2 and Comparative Example 1 correspond to trajectories shown by a thick solid line and a thin solid line, respectively. It should be noted that in order to perform comparison with the impedance of Embodiment 2, the radio frequency amplifier according to Comparative Example 1 has three series resonant circuits, and L1 and C1, L2 and C2, and L3 and C3 are selected such that the resonant frequencies of these three series resonance circuits are f1=90 MHz, f2=450 MHZ, and f3=10 MHz, respectively. From the trajectory of Comparative Example 1, the resonant frequencies of the first, second, and third series resonant circuits can be confirmed near 90 MHz, near 450 MHZ, and near 10 MHZ, respectively; however, the maximum values of the impedance due to antiresonance are observed near 60 MHz and 380 MHz, which are frequencies between the respective resonance points. In the trajectory of Embodiment 2, it can be confirmed that the antiresonance observed in Comparative Example 1 is sufficiently inhibited, and the impedance at difference frequencies is reduced over an extremely wide bandwidth of 10 MHz to 400 MHZ.

FIG. 9 is a diagram illustrating the results of a simulation of the insertion loss (vertical axis) from drain D of transistor 1 to output terminal 16, for the radio frequency amplifiers according to Embodiment 2 and Comparative Example 1. In order to compare the loss inside the radio frequency amplifiers, the calculated results exclude loss due to reflection. In all circuits, circuit constants have been selected such that the insertion loss is lowest around 3 GHZ. The insertion loss in Comparative Example 1, which has no resistance components in the first series resonant circuit and the second series resonant circuit, and the insertion loss in Embodiment 2 have almost the same results.

From the results of FIG. 8 and FIG. 9, it can be confirmed that radio frequency amplifier 210 according to Embodiment 2 can stably reduce the difference frequency impedance over a wider bandwidth by inhibiting the generation of antiresonance (refer to FIG. 8), with almost no increase in the insertion loss of the circuit (refer to FIG. 9). As described above, in radio frequency amplifier 210 according to the present embodiment, in addition to first series resonant circuit 5 and second series resonant circuit 6, shunt circuit 243 is further connected between node 160 and ground 161, includes a third inductor element (transmission line 50) and third capacitor elements (bypass capacitors 51 and 52) that are connected in series, and has third series resonant circuit 49 that has third resonant frequency f3 that is different from first resonant frequency f1 and second resonant frequency f2. This makes it possible to reduce the impedance at the three difference frequencies, whereby the impedance at difference frequencies is reduced over a wider bandwidth, resulting in the realization of radio frequency amplifier 210 that has low intermodulation distortion and is capable of highly efficient operation.

Furthermore, the inductor element and the capacitor elements that constitute third series resonant circuit 49 are transmission line 50 and bypass capacitors 51 and 52 that are included in the drain bias circuit that supplies a bias voltage to drain D. This can simplify the circuit due to the series resonant circuit that reduces the difference frequency impedance also serving as the drain bias circuit.

Third connection point 49a of third series resonant circuit 49 and first connection point 5a of first series resonant circuit 5 are connected by a series circuit that includes: a first impedance element (resistor 64) that includes a resistance component; and a direct current (DC)-blocking element (capacitor 65). Accordingly, the direct current voltage from power supply terminal 15 being applied to first series resonant circuit 5 is avoided.

### Variation of Embodiment 2

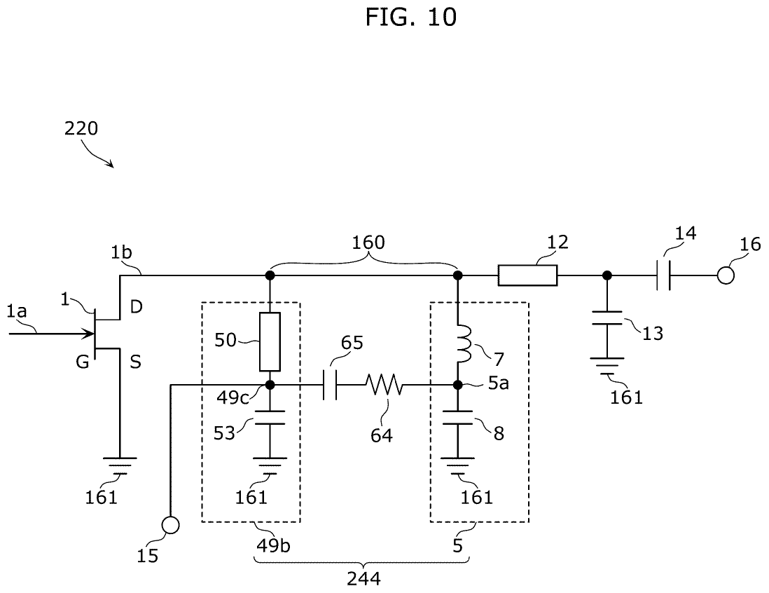

FIG. 10 is a circuit diagram illustrating a configuration example of radio frequency amplifier 220 according to a variation of Embodiment 2. The circuit of radio frequency amplifier 220 in FIG. 10 has a configuration in which second series resonant circuit 6 has been removed from the circuit of radio frequency amplifier 210 according to Embodiment 2 illustrated in FIG. 7. In other words, third series resonant circuit 49b is formed. In third series resonant circuit 49b, a drain bias circuit is constituted by the inductance component included in transmission line 50, which is an example of the third inductor element, and bypass capacitor 53, which is an example of the third capacitor element. Furthermore, third connection point 49c, which is the connection point between transmission line 50 and bypass capacitor 53, and first connection point 5a, which is the connection point between inductor 7 and capacitor 8 that form first series resonant circuit 5, are connected using resistor 64 and capacitor 65 that are connected in series. Resistor 64 is an example of the first impedance element and capacitor 65 is an example of the DC-blocking element. In other words, in this variation, shunt circuit 244 has: first series resonant circuit 5; third series resonant circuit 49b; and resistor 64 and capacitor 65 that are connected in series and bridge these series resonant circuits.

As described in Comparative Example 1 and Comparative Example 2, when a plurality of resonant circuits are present and their resonant frequencies are different, antiresonance occurs, creating a band where the impedance is maximal; however, in this variation of the present embodiment, as in Embodiments 1 and 2, the antiresonance can be inhibited by connecting the connection points between the inductors and the capacitors in each resonant circuit using a resistor.

### Embodiment 3

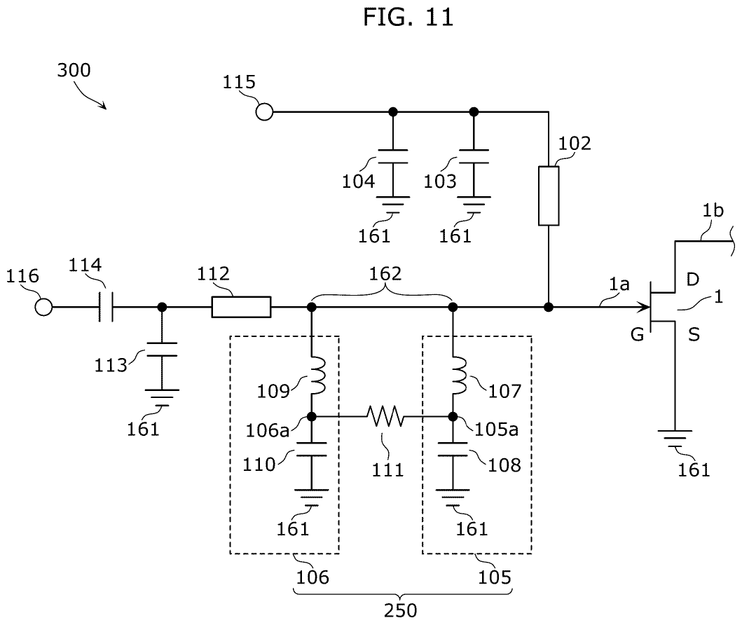

FIG. 11 is a circuit diagram illustrating a configuration example of radio frequency amplifier 300 according to Embodiment 3. In radio frequency amplifier 300, the features described in Embodiment 1 are applied to gate G of transistor 1. In other words, this achieves a reduction in the impedance, as observed from gate G of transistor 1, by left-right inverting the circuit from drain D of transistor 1 to output terminal 16 described in Embodiment 1, centered on transistor 1 (in other words, the input side and the output side are inverted), to constitute input terminal 116 from gate G of transistor 1.

In other words, radio frequency amplifier 300 includes shunt circuit 250, which is connected between ground 161 and node 162 on input line 1a connected to gate G of transistor 1, as a circuit that corresponds to shunt circuit 240 of Embodiment 1. Shunt circuit 250 includes: first series resonant circuit 105 that includes inductor 107 and capacitor 108 that are connected in series at first connection point 105a; second series resonant circuit 106 that includes inductor 109 and capacitor 110 that are connected in series at second connection point 106a; and resistor 111, which is an example of the first impedance element that includes a resistance component, that connects first connection point 105a to second connection point 106a.

Furthermore, radio frequency amplifier 300 further includes, as a gate bias circuit that corresponds to the drain bias circuit in Embodiment 1, bypass capacitors 103 and 104, which are connected to power supply terminal 115, and transmission line 102.

Furthermore, radio frequency amplifier 300 further includes, as an input matching circuit that corresponds to the output matching circuit in Embodiment 1, capacitors 113 and 114 and transmission line 112.

Here, the circuit parts constituting radio frequency amplifier 300 may have the same property values as the corresponding circuit parts in Embodiment 1, or may have different property values. As an example, the circuit parts constituting radio frequency amplifier 300 have the same property values as the corresponding circuit parts in Embodiment 1. In this case, resonant frequency f1 of first series resonant circuit 105 and resonant frequency f2 of second series resonant circuit 106 are, respectively, f1=650 MHz and f2=900 MHz, as in Embodiment 1.

Thus, radio frequency amplifier 300 according to the present embodiment includes the following, which constitute shunt circuit 250 provided on the input side of transistor 1: first series resonant circuit 105; second series resonant circuit 106; and the first impedance element (resistor 111) that includes a resistance component and bridges these series resonant circuits. Therefore, the impedance at difference frequencies can be reduced over a wide bandwidth on the input side of transistor 1, resulting in low intermodulation distortion and allowing for highly efficient operation.

It should be noted that the present embodiment does not necessarily require the circuit configuration of Embodiment 1 or 2 or of the variation of Embodiment 2, and may be performed together with the circuit configuration of Embodiment 1 or 2 or of the variation of Embodiment 2, or may be performed independently.

In the case of performance together with Embodiment 1, in addition to the impedance reduction effect of Embodiment 1, intermodulation distortion reduction can be achieved by also reducing the impedance at gate G of transistor 1 in Embodiment 3.

### Embodiment 4

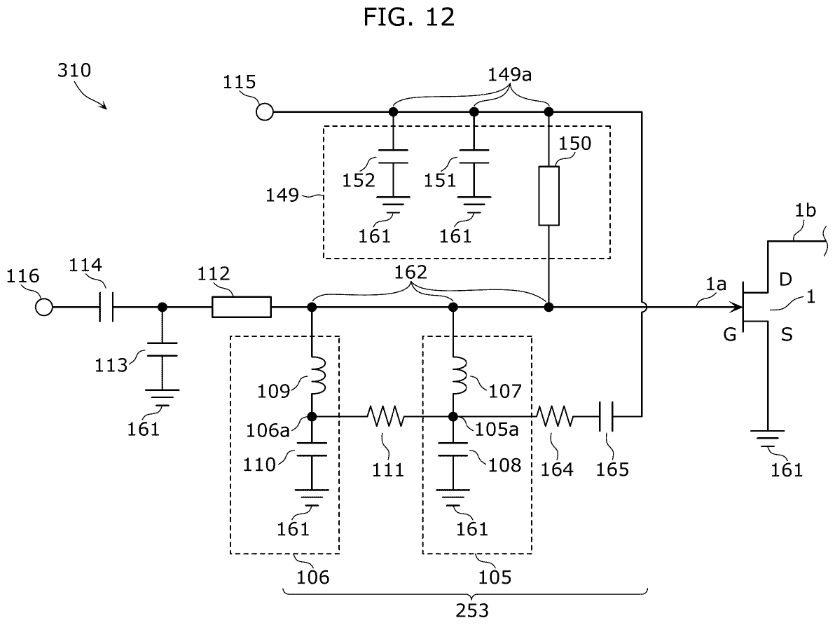

FIG. 12 is a circuit diagram illustrating a configuration example of radio frequency amplifier 310 according to Embodiment 4. In radio frequency amplifier 310, the features described in Embodiment 2 are applied to gate G of transistor 1. In other words, this achieves a reduction in the impedance, as observed from gate G of transistor 1, by left-right inverting the circuit from drain D of transistor 1 to output terminal 16 described in Embodiment 1, centered on transistor 1 (in other words, the input side and the output side are inverted), to constitute input terminal 116 from gate G of transistor 1.

Describing by comparison with Embodiment 3, radio frequency amplifier 310 has basically the same configuration as Embodiment 3, but is different from Embodiment 3 in that radio frequency amplifier 310 includes: as shunt circuit 253, in addition to first series resonant circuit 105 and second series resonant circuit 106, third series resonant circuit 149 constituted from transmission line 150 and bypass capacitors 151 and 152; and further includes resistor 164 and capacitor 165 that are connected in series and connect third connection point 149a of third series resonant circuit 149 to first connection point 105a of first series resonant circuit 105.

The circuit parts constituting radio frequency amplifier 310 may have the same property values as the corresponding circuit parts in Embodiment 2, or may have different property values. As an example, the circuit parts constituting radio frequency amplifier 310 have the same property values as the corresponding circuit parts in Embodiment 2. In this case, resonant frequency f1 of first series resonant circuit 105, resonant frequency f2 of second series resonant circuit 106, and resonant frequency f3 of third series resonant circuit 149 are, respectively, f1=650 MHZ, f2=900 MHZ, and f3=10 MHZ, as in Embodiment 2.

Thus, radio frequency amplifier 310 according to the present embodiment includes, on the input side of transistor 1, the three series resonant circuits (first series resonant circuit 105, second series resonant circuit 106, and third series resonant circuit 149) and the first impedance element that includes a resistance component and bridges these series resonant circuits. Therefore, the impedance at the three difference frequencies can be reduced on the input side of transistor 1, whereby the impedance at difference frequencies is reduced over a wider bandwidth, resulting in low intermodulation distortion and allowing for highly efficient operation.

It should be noted that the present embodiment does not necessarily require the circuit configuration of Embodiment 1 or 2 or of the variation of Embodiment 2, and may be performed together with the circuit configuration of Embodiment 1 or 2 or of the variation of Embodiment 2, or may be performed independently.

In the case of performance together with Embodiment 2, in addition to the impedance reduction effect of Embodiment 2, intermodulation distortion reduction can be achieved by also reducing the impedance at gate G of transistor 1 in Embodiment 4.

### Variation of Embodiment 4

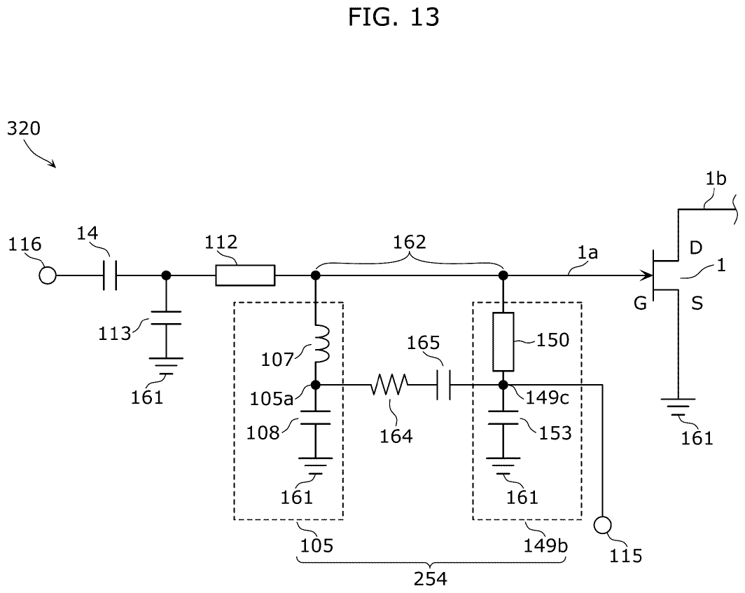

FIG. 13 is a circuit diagram illustrating a configuration example of radio frequency amplifier 320 according to a variation of Embodiment 4. In radio frequency amplifier 320, the features described in the variation of Embodiment 2 are applied to gate G of transistor 1. In other words, this achieves a reduction in the impedance, as observed from gate G of transistor 1, by left-right inverting the circuit from drain D of transistor 1 to output terminal 16 described in the variation of Embodiment 2, centered on transistor 1 (in other words, the input side and the output side are inverted), to constitute input terminal 116 from gate G of transistor 1.

Describing by comparison with Embodiment 4, radio frequency amplifier 320 has a configuration in which second series resonant circuit 106 has been removed from the configuration of radio frequency amplifier 310 according to Embodiment 4 illustrated in FIG. 12. In other words, shunt circuit 254 has: first series resonant circuit 105; third series resonant circuit 149b; and resistor 164 and capacitor 165 that are connected in series and connect first connection point 105a of first series resonant circuit 105 to third connection point 149c of third series resonant circuit 149b.

Thus, radio frequency amplifier 320 according to the present embodiment includes the following, which constitute shunt circuit 254 provided on the input side of transistor 1: first series resonant circuit 105; third series resonant circuit 149b; and resistor 164 and capacitor 165 that are connected in series and bridge these series resonant circuits. Therefore, the impedance at difference frequencies can be reduced over a wide bandwidth on the input side of transistor 1, resulting in low intermodulation distortion and allowing for highly efficient operation.

It should be noted that the circuit parts constituting radio frequency amplifier 320 may have the same property values as the corresponding circuit parts in the variation of Embodiment 4, or may have different property values.

Furthermore, the present embodiment does not necessarily require the circuit configuration of Embodiment 1 or 2 or of the variation of Embodiment 2, and may be performed together with the circuit configuration of Embodiment 1 or 2 or of the variation of Embodiment 2, or may be performed independently.

In the case of performance together with the variation of Embodiment 2, in addition to the impedance reduction effect due to the variation of Embodiment 2, intermodulation distortion reduction can be achieved by also reducing the impedance at gate G of transistor 1 in the variation of Embodiment 4.

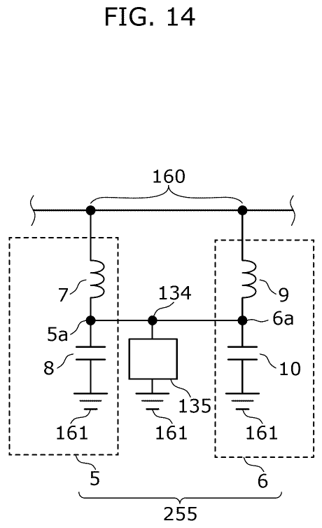

FIG. 14 is a circuit diagram illustrating a configuration example of shunt circuit 255 including a bridge circuit other than a resistor. Embodiments 1 to 4 and their variations disclosed examples in which the shunt circuit was a shunt circuit including a bridge circuit in which connection points between inductors and capacitors of a plurality of series resonant circuits are connected using a resistor. FIG. 14 illustrates an example of shunt circuit 255 that includes a bridge circuit in which bridging impedance element 135 is disposed in shunt. Bridging impedance element 135 is acceptable as long as it is an element that includes a resistor, and may include a DC-blocking function if necessary, when DC voltage is applied to first series resonant circuit 5 and second series resonant circuit 6. For example, by providing an element in which a resistor and a capacitor are connected in series as bridging impedance element 135, DC can be blocked by the capacitor while also having a resistance component. Thus, in FIG. 14, bridging impedance element 135 is connected between ground 161 and node 134, at which first connection point 5a and second connection point 6a are shorted, and may include a DC-blocking element. Node 134 is the location at which first connection point 5a and second connection point 6a are shorted.

Even in the case of a radio frequency amplifier that includes shunt circuit 255 including a bridge circuit in which bridging impedance element 135 is disposed in shunt, the impedance at difference frequencies is reduced over a wide bandwidth, resulting in low intermodulation distortion and allowing for highly efficient operation, as in Embodiment 1 and the like.

It should be noted that the shunt circuit illustrated in FIG. 14 can be applied as the shunt circuit of the radio frequency amplifier according to any of Embodiments 1 to 4 and the variations thereof.

Although the radio frequency amplifier according to the present disclosure has been described above based on Embodiments 1 to 4 and the variations thereof, the present disclosure is not intended to be limited to these embodiments and variations. Other forms obtained by making various modifications to the present embodiments and variations that can be conceived by those skilled in the art, or through a combination of the constituent elements in different embodiments and variations described above may be included in the scope of the present disclosure, unless such modifications and combination depart from the spirit of the present disclosure.

### INDUSTRIAL APPLICABILITY

The radio frequency amplifier according to the present disclosure includes a circuit that reduces the impedance of the difference frequency over a wide bandwidth even if the occupied bandwidth increases and the difference frequencies increase, making it possible to provide a radio frequency amplifier that has low intermodulation distortion and is capable of highly efficient operation. The radio frequency amplifier according to the present disclosure can be utilized as a radio frequency amplifier for a base station or a terminal for a mobile phone, satellite communication, or the like.

1. A radio frequency amplifier comprising:
a transistor;
an input line that transmits a radio frequency (RF) signal to be inputted into the transistor;
an output line that transmits an RF signal that is outputted from the transistor; and
a shunt circuit that is connected between ground and the input line or the output line, wherein
the shunt circuit includes:
a first series resonant circuit that is connected between a node and the ground, includes a first inductor element and a first capacitor element that are connected in series, and has a first resonant frequency, the node being on the input line or the output line;
a second series resonant circuit that is connected between the node and the ground, includes a second inductor element and a second capacitor element that are connected in series, and has a second resonant frequency that is different from the first resonant frequency; and
a first impedance element that is connected between a first connection point and a second connection point and includes a resistance component, the first connection point being a connection location between the first inductor element and the first capacitor element, the second connection point being a connection location between the second inductor element and the second capacitor element.

2. The radio frequency amplifier according to claim 1, wherein
the transistor includes:
a gate;
a drain; and
a source, and
the first inductor element and the first capacitor element are a transmission line and a bypass capacitor, respectively, that are included in a drain bias circuit that supplies a bias voltage to the drain, or are included in a gate bias circuit that supplies a bias voltage to the gate.

3. The radio frequency amplifier according to claim 2, wherein
the first connection point and the second connection point are connected by a series circuit, the series circuit including the first impedance element and a direct current (DC)-blocking element.

4. The radio frequency amplifier according to claim 1, wherein
the first impedance element is a resistor element.

5. The radio frequency amplifier according to claim 1, wherein
the shunt circuit further includes a third series resonant circuit that is connected between the node and the ground, includes a third inductor element and a third capacitor element that are connected in series, and has a third resonant frequency that is different from the first resonant frequency and the second resonant frequency.

6. The radio frequency amplifier according to claim 1, wherein
in the first series resonant circuit, the first inductor element is connected closer to the node than the first capacitor element is.

7. The radio frequency amplifier according to claim 1, wherein
the first impedance element is connected between a node and the ground and includes a direct current (DC)-blocking element, the node being a node at which the first connection point and the second connection point are shorted.

8. The radio frequency amplifier according to claim 1, wherein
an impedance element that blocks signals of the first resonant frequency and the second resonant frequency is absent between the shunt circuit and a gate or a drain of the transistor.

9. The radio frequency amplifier according to claim 8, wherein
an impedance of the impedance element is 20Ω or greater.

10. The radio frequency amplifier according to claim 1, wherein
the resistance component is 60Ω or less.

11. The radio frequency amplifier according to claim 1, wherein
the resistance component is 30Ω or greater.

12. The radio frequency amplifier according to claim 5, wherein
the first resonant frequency, the second resonant frequency, and the third resonant frequency are arranged at equal intervals on a logarithmic scale.
